(19) United States
(12) Patent Application Publication
(10) Pub. No.: US 2012/0319123 A1
(43) Pub. Date: Dec. 20, 2012

(54) Display Device and Method of Manufacturing the Same

(75) Inventors: Byung-Uk Han, Asan-si (KR); Oh-Seob Kwon, Seongnam-si (KR); Jung-Jun Im, Suwon-si (KR); Dong-Seop Park, Cheonan-si (KR)

(73) Assignee: SAMSUNG MOBILE DISPLAY CO., LTD., Yongin-City (KR)

(21) Appl. No.: 13/453,466

(22) Filed: Apr. 23, 2012

(30) Foreign Application Priority Data
Jun. 14, 2011 (KR) 10-2011-0057516

(51) Int. Cl. H01L 33/08

(52) U.S. Cl. 257/72; 438/34; 257/E33.012

(57) ABSTRACT

A display device may include a first substrate comprising a display region and a non-display region surrounding the display region, a first metal wiring formed in the display region of the first substrate, a second metal wiring formed in the non-display region of the first substrate, a sealing member formed on the second metal wiring, and a second substrate disposed on the sealing member so as to face the first substrate. The first metal wiring and the second wiring are made of the same material.

### CLAIM OF PRIORITY

This application makes reference to, incorporates the same herein, and claims all benefits accruing under 35 U.S.C. §119 from an application earlier filed in the Korean Intellectual Property Office on the 14^{th} of Jun. 2011 and there duly assigned Serial No. 10-2011-0057516.

### BACKGROUND OF THE INVENTION

1. Field of the Invention

The present invention relates to a display device and a method of manufacturing the same, and more particularly, to a display device which is sealed using metal wirings, and a method of manufacturing the display device.

2. Description of the Related Art

The rapid development of the information technology (IT) industry is dramatically increasing the use of display devices. Recently, there have been demands for display devices which are lightweight and thin, consume low power and provide high resolution. To meet these demands, liquid crystal displays (LCDs) or organic light-emitting display devices (OLEDs) using organic light-emitting characteristics are being developed.

Internal elements of these display devices can easily collapse by interacting with oxygen and moisture which penetrate into the display devices from a surrounding environment. In the manufacture of these display devices, a sealing process is commonly performed in order to protect the internal elements of the display devices by sealing the display devices.

To seal a display device during the manufacture of the display device, a bonding member may be coated between a lower substrate and an upper substrate, and may be fusion-bonded to the lower and upper substrates using a laser. However, this sealing method takes a long time, reduces the life of a panel because it is difficult to completely block external moisture during a sealing process, and requires expensive laser equipment.

Apart from the laser fusion-bonding method described above, a display device can also be sealed using Joule heat generated by a wiring portion. In the sealing method using Joule heat, the wiring portion which generates Joule heat is formed on an upper substrate (an encapsulation substrate). In this case, however, a mask process should be additionally performed on the upper substrate in order to form the wiring portion, and another mask process should also be performed in order to form an insulator structure so as to increase the adhesion of an interface between a bonding member, such as a frit material, and the wiring portion.

### SUMMARY OF THE INVENTION

Aspects of the present invention provide a display device which may include wirings formed on an upper substrate without an additional mask process, and which has improved mechanical strength, and a method of manufacturing the display device.

However, aspects of the present invention are not restricted to the ones set forth herein. The above and other aspects of the present invention will become more apparent to one of ordinary skill in the art to which the present invention pertains by referencing the detailed description of the present invention given below.

According to an aspect of the present invention, there is provided a display device which may include a first substrate comprising a display region and a non-display region surrounding the display region, a first metal wiring formed on the display region of the first substrate, a second metal wiring formed on the non-display region of the first substrate, a sealing member formed on the second metal wiring, and a second substrate disposed on the sealing member so as to face the first substrate, wherein the first metal wiring and the second wiring are made of the same material.

According to another aspect of the present invention, there is provided a display device which may include a first substrate comprising a display region and a non-display region surrounding the display region, a metal wiring formed on the non-display region of the first substrate and shaped like a trench, a sealing member formed on the metal wiring and filling the trench of the metal wiring, and a second substrate disposed on the sealing member so as to face the first substrate.

According to another aspect of the present invention, there is provided a display device which may include a first substrate comprising a display region and a non-display region surrounding the display region, a first metal wiring formed on the display region of the first substrate, an intermediate layer formed on the non-display region of the first substrate and comprising one or more insulating layers and a second metal wiring, a sealing member formed on the intermediate layer, and a second substrate disposed on the sealing member so as to face the first substrate, wherein the first metal wiring and the second wiring are made of the same material.

According to an aspect of the present invention, there is provided a method of manufacturing a display device, the method may include forming a first substrate which comprises a display region and a non-display region surrounding the display region, forming a first metal wiring on the display region of the first substrate, forming a second metal wiring on the non-display region at the same time that the first metal wiring is formed using the same material as that of the first metal wiring and to a thickness equal to that of the first metal wiring, forming a sealing member on the second metal wiring, and placing a second substrate on the sealing member so as to face the first substrate.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a cross-sectional view of a display device according to an exemplary embodiment of the present invention;

FIG. 2 is a plan view of the display device shown in FIG. 1;

FIG. 3 is a cross-sectional view taken along the line III-III of FIG. 2;

FIGS. 4 thru 11 are cross-sectional views of display devices according to other exemplary embodiments of the present invention;

FIG. 12 is a cross-sectional view taken along the line XII-XII of FIG. 2;

FIGS. 13 thru 17 are cross-sectional views of display devices according to other exemplary embodiments of the present invention; and

FIG. 18 is a flowchart illustrating a method of manufacturing a display device according to an exemplary embodiment of the present invention.

### DETAILED DESCRIPTION OF THE INVENTION

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, sizes and relative sizes of elements may be exaggerated for clarity.

Like reference numerals refer to like elements throughout the specification. As used herein, the term “and/or” includes any and all combinations of one or more of the associated listed items.

The terminology used herein is for the purpose of describing particular embodiments only and is not intended to be limiting of the invention. As used herein, the singular forms are intended to include the plural forms as well, unless the context clearly indicates otherwise. It will be further understood that the terms “comprises” and/or “made of,” when used in this specification, specify the presence of stated components, steps, operations, and/or elements, but do not preclude the presence or addition of one or more other components, steps, operations, elements, and/or groups thereof.

It will be understood that, although the terms first, second, third, etc. may be used herein to describe various elements, these elements should not be limited by these terms. These terms are only used to distinguish one element from another element. Thus, a first element discussed below could be termed a second element without departing from the teachings of the present invention

Embodiments of the invention are described herein with reference to plan and cross-sectional illustrations which are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature, and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning which is consistent with their meaning in the context of the relevant art and will not be interpreted in an idealized or overly formal sense unless expressly so defined herein.

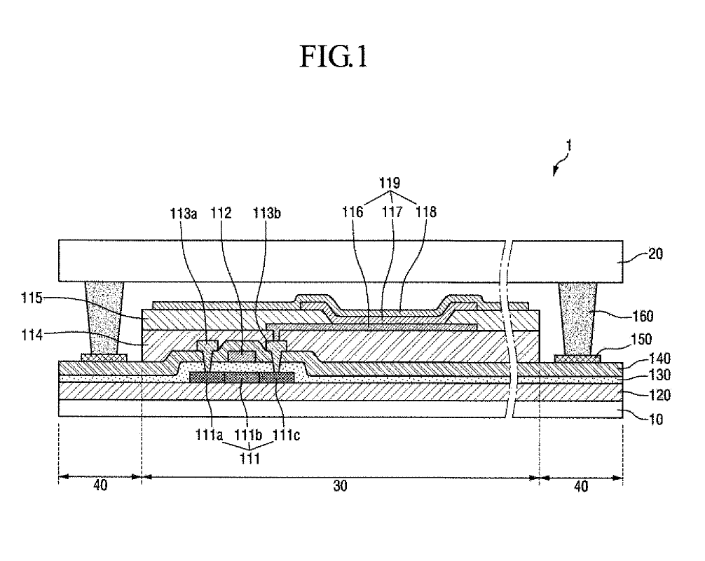

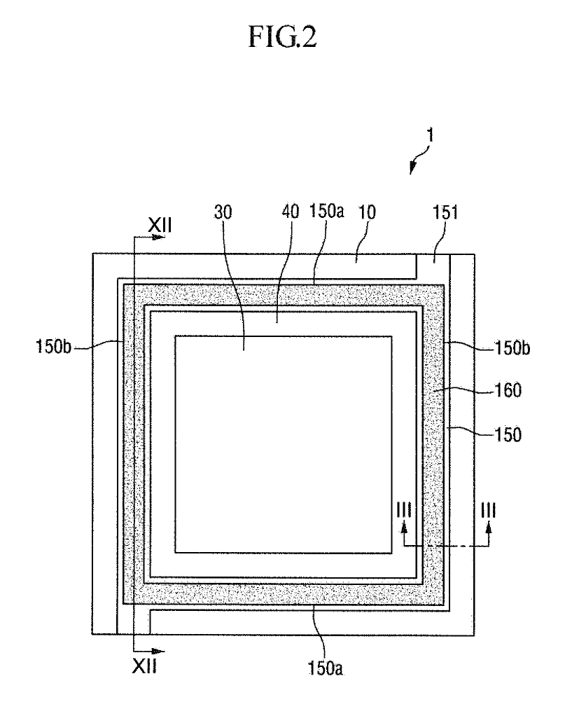

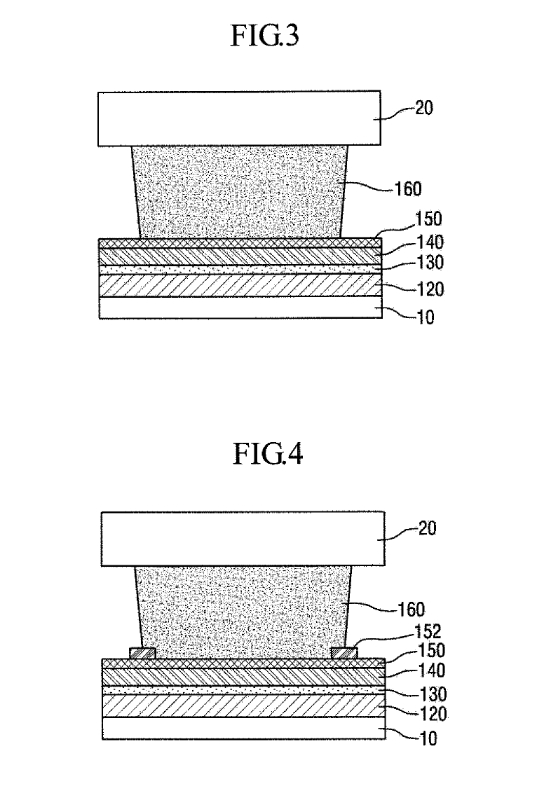

FIG. 1 is a cross-sectional view of a display device according to an exemplary embodiment of the present invention; FIG. 2 is a plan view of the display device shown in FIG. 1; and FIG. 3 is a cross-sectional view taken along the line III-III of FIG. 2.

Referring to FIGS. 1 thru 3, the display device 1 according to the current exemplary embodiment includes a first substrate 10, a first metal wiring formed on a display region 30 of the first substrate 10, a second metal wiring 150 formed on a non-display region 40 of the first substrate 10, a sealing member 160 formed on the second metal wiring 150, and a second substrate 20 disposed on the sealing member 160 and facing the first substrate 10.

The display device 1 according to the current exemplary embodiment may be an organic light-emitting display device (OLED), a liquid crystal display (LCD), or the like. The case where the display device 1 is an OLED will hereinafter be described.

The first substrate 10 includes the display region 30 and the non-display region 40 surrounding the display region 30. The display region 30 of the first substrate 10 is located in the center of the first substrate 10 and may be a region of the first substrate 10 on which a light-emitting portion 110 is disposed. The non-display region 40 of the first substrate 10 may be a region surrounding the display region 30 of the first substrate 10 and may be a region of the first substrate 10 on which the light-emitting portion 110 is not disposed. The first substrate 10 may be made of glass.

A buffer layer 120 may be formed on the first substrate 10. The buffer layer 120, which is an insulating layer, may be formed on the entire surfaces of the display region 30 and the non-display region 40 of the first substrate 10. The buffer layer 120 may prevent diffusion of impurity ions and penetration of moisture or external air, and may planarize a surface. In some embodiments, the buffer layer 120 may include one or more insulating layers. For example, the buffer layer 120 may be formed by alternately stacking a SiO₂ layer and a SiNₓ layer.

An active layer 111 may be formed on the buffer layer 120. The active layer 111 may be formed particularly in a thin-film transistor (TFT) region on the display region 30. The active layer 111 may be divided into a source region 111a, a gate region 111b, and a drain region 111c according to characteristics of electrodes disposed thereon. The active layer 111 may be made of a semiconductor material.

A gate insulating layer 130 may be formed on the active layer 111. The gate insulating layer 130 may be formed on the entire surfaces of the display region 30 and the non-display region 40. The gate insulating layer 130 may have a single-layer structure or a multilayer structure. In addition, the gate insulating layer 130 may be made of an organic material, an inorganic material, or a compound of an organic material and an inorganic material. In some embodiments, the gate insulating layer 130 may be formed by alternately stacking a SiO₂ layer and a SiN_{X} layer.

A gate electrode 112 may be formed on a region of the gate insulating layer 130 which corresponds to the gate region 111b.

An interlayer insulating film 140 may be formed on the gate insulating layer 130. The interlayer insulating film 140 may be formed on the entire surfaces of the display region 30 and the non-display region 40. The interlayer insulating film 140 may have a single-layer structure or a multilayer structure. In addition, the interlayer insulating film 140 may be made of an organic material, an inorganic material, or a compound of an organic material and an inorganic material. In some embodiments, the interlayer insulating film 140 may be formed by alternately stacking a SiO₂ layer and a SiN_{X} layer.

A source electrode 113a and a drain electrode 113b are formed on the interlayer insulating film 140, in particular, in the TFT region on the display region 30. The source electrode 113a and the drain electrode 113b may penetrate the interlayer insulating film 140 and the gate insulating layer 130 so as to contact the active layer 111. The source electrode 113 a may contact the source region 111a of the active layer 111, and the drain electrode 113b may contact the drain region 111c of the active layer 111.

The stack structure of a TFT on the display region 30 is not limited to the structure described above. TFTs having various structures can all be employed.

A planarization layer 114 may be formed on the source electrode 113a, the drain electrode 113b, and the interlayer insulating film 140 of the display region 30. The planarization layer 114 may be made of one or more organic insulating materials selected from polyimide, polyamide, acrylic resin, benzocyclobutene, and phenolic resin. In some embodiments, the planarization layer 114 may be made of an inorganic insulating material.

A pixel electrode 116 may be formed on the planarization layer 114. The pixel electrode 116 may be brought into contact with the source electrode 113a or the drain electrode 113b through a via hole and may thus be electrically connected to the source electrode 113a or the drain electrode 113b. A pixel defined layer 115 may be formed on the pixel electrode 116, and a pixel aperture may be formed in the pixel defined layer 115 so as to expose at least a portion of the pixel electrode 116. A light-emitting member 117 may be formed on the portion of the pixel electrode 116 exposed by the pixel aperture.

The light-emitting member 117 may be a small molecule organic film or a polymer organic film. The light-emitting member 117 may be formed by stacking a hole injection layer, a hole transport layer, an emission layer, an electron transport layer, and an electron injection layer in a single layer or multilayer structure. Examples of an usable organic material include copper phthalocyanine (CuPc), N,N′-Di(naphthalene-1-yl)-N,N′-diphenyl-benzidine (NPB), tris-8-hydroxyquinoline aluminum (Alq3), and other suitable various materials.

A counter electrode 118 may be formed on the light-emitting member 117 so as to cover the entire surface of the display region 30. The pixel electrode 116 and the counter electrode 118 are insulated from each other by the light-emitting member 117. Voltages of different polarities are applied to the light-emitting member 117, thus causing the light-emitting member 117 to emit light.

An organic light-emitting 119 may consist of the pixel electrode 116, the light-emitting member 117 and the counter electrode 118. The pixel electrode 116 may function as an anode, and the counter electrode 118 may function as a cathode electrode. In some embodiments, the pixel electrode 116 may function as a cathode electrode, and the counter electrode 118 may function as an anode.

The first metal wiring is formed on the display region 30 of the first substrate 10. The first metal wiring may be any one of a plurality of metal layers formed on the display region 30. The first metal wiring may be the gate electrode 112 formed on the display region 30. In some embodiments, the first metal wiring may be the source electrode 113a, the drain electrode 113b, an anode electrode or a cathode electrode formed on the display region 30.

The second metal wiring 150 is formed on the non-display region 40 of the first substrate 10. In some embodiments, after the buffer layer 120, the gate insulating layer 130 and the interlayer insulating film 140 are sequentially stacked on the non-display region 40 of the substrate 10, the second metal wiring 150 may be formed on the non-display region 40 of the first substrate 10.

The second metal wiring 150 may be formed on the non-display region 40 of the first substrate 10 at the same time that the first metal wiring is formed on the display region 30 of the first substrate 10. The second metal wiring 150 may be made of the same material as the first metal wiring and may have substantially the same thickness as the first metal wiring. In the embodiment of FIG. 3, the first metal wiring is the source electrode 113a and the drain electrode 113b formed on the display region 30, and the second metal wiring 150 is made of the same material as the first metal wiring, that is, the source electrode 113a and the drain electrode 113b.

The sealing member 160 is formed on the second metal wiring 150. The sealing member 160 is a material used to seal elements inside the display device. The sealing member 160 is formed on the second metal wiring 150 which is formed in the non-display region 40 surrounding the display region 30.

The sealing member 160 formed on the second metal wiring 150 is melted and hardened by heat, e.g, Joule heat supplied from the second metal wiring 150, thereby bonding the first substrate 10 and the second substrate 20 together so as to seal the display device 1.

Sealing member 160 may be a thermosetting material. In some embodiments, the sealing member 160 may be made of at least one material selected from K₂O, Sb₂O₃, ZnO, TiO₂, Al₂O₃, WO₃, SnO, PbO, V₂O₅, Fe₂O₃, P₂O₅, B₂O₃, and SiO₂. However, examples of the material which forms the sealing member 160 are not limited to the above materials, and the sealing member 160 can be made of any thermosetting material.

The second substrate 20 is an encapsulation substrate and is disposed on the sealing member 160 so as to face the first substrate 10. The second substrate 20 is bonded to the first substrate 10 by the sealing member 160, thereby sealing the display device 1. The second substrate 20 may be made of glass.

The second metal wiring 150 may be supplied with power and provide heat to the sealing member 160. When a voltage is applied to the second metal wiring 150, the second metal wiring 150 generates Joule heat, and the sealing member 160 (i.e., a thermosetting material) is melted and hardened by the Joule heat supplied by the second metal wiring 150, thereby bonding the first substrate 10 and the second substrate 20 together.

The second metal wiring 150 may include one or more additional wirings 151 (see FIG. 2) to receive power from an external source. Each of the additional wirings 151 may be an extension of the second metal wiring 150 or a separate wiring additionally connected to the second metal wiring 150. The additional wirings 151 may be made of conductive metal. Also, each of the additional wirings 151 may be made of the same material as the second metal wiring 150, and may have substantially the same thickness as the second metal wiring 150.

In the embodiment of FIG. 2, the second metal wiring 150 formed on the non-display region of the first substrate 10 includes two additional wirings 151 to receive power from an external source. However, the present invention is not limited thereto, and the second metal wiring 150 can also include one additional wiring 151. In some embodiments, the second metal wiring 150 may include a plurality of additional wirings 151 which connect the second metal wiring 150 to an external power source.

Forming an additional wiring portion on the first substrate 10 or the second substrate 20 requires an additional mask process in the manufacture of the display device. Such an additional mask process may further complicate the process, and may be inefficient in terms of cost and time since additional equipment should be committed.

In the current exemplary embodiment of the present invention, the second metal wiring 150 providing heat to the sealing member 160 may be formed on the non-display region 40 of the first substrate 10 at the same time that the first metal wiring is formed on the display region 30 of the first substrate 10. For example, if the first metal wiring is the gate electrode 112, when the gate electrode 112 is formed on the display region 30, the second metal wiring 150 may also be formed on the non-display region 40 using the same material as that of the gate electrode 112 formed on the display region 30, and may be formed to a thickness substantially equal to that of the gate electrode 112. When the first metal wiring is the source electrode 113a or the drain electrode 113b, the second metal wiring 150 may be formed at the same time as the source electrode 113a or the drain electrode 113b. When the first metal wiring is an anode electrode or a cathode electrode, the second metal wiring 150 may also be formed in the same way as described above.

If the second metal wiring 150 is formed at the same time that the first metal wiring is formed on the display region 30 as described above, an additional mask process for forming the second metal wiring 150 can be omitted. Therefore, the process can be simplified compared to the process when a wiring portion for providing heat to the sealing member 160 is formed using an additional mask process, and increased efficiency can be obtained in terms of cost and time.

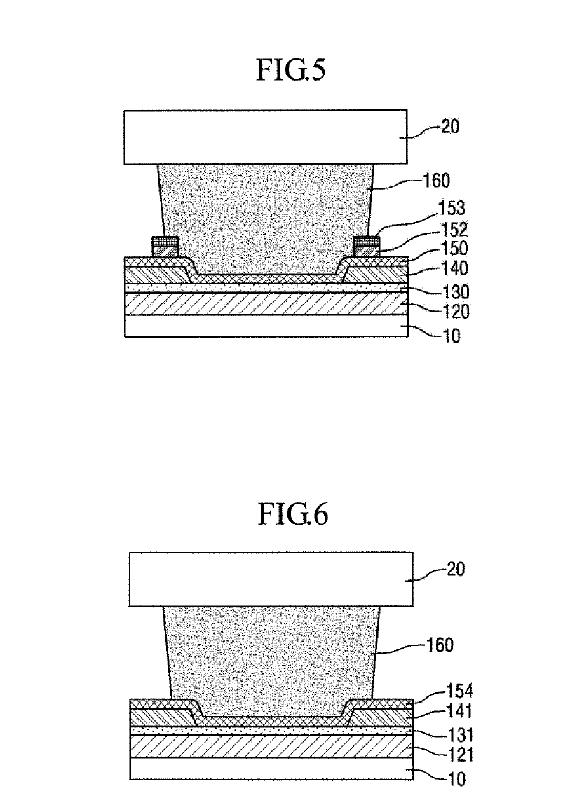

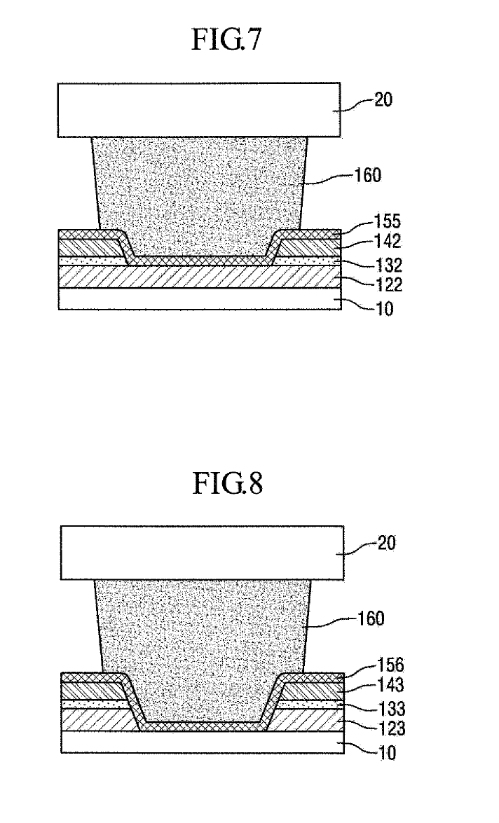

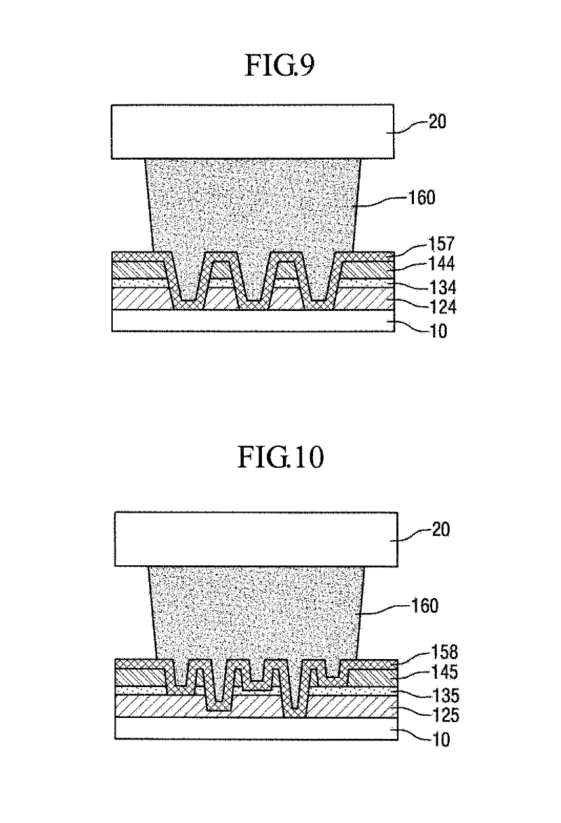

FIGS. 4 and 5 are cross-sectional views of display devices according to other exemplary embodiments of the present invention.

Referring to FIG. 4, the display device according to the current exemplary embodiment is different from the display device according to the exemplary embodiment of FIG. 3 in that it further includes a third metal wiring 152 disposed on second metal wiring 150 so as to be in contact with the second metal wiring 150. Referring to FIG. 5, the display device according to the current exemplary embodiment is different from the display device according to the exemplary embodiment of FIG. 4 in that it further includes a fourth metal wiring 153 disposed on third metal wiring 152 so as to be in contact with the third metal wiring 152.

The third metal wiring 152 may be disposed on the second metal wiring 150 so as to be in contact with the second metal wiring 150, and at least a portion of a top surface of the third metal wiring 152 may contact a sealing member 160 formed on the second metal wiring 150. In some embodiments, as shown in FIG. 4, the third metal wiring 152 may be located on the second metal wiring 150 and at both edges of the sealing member 160, and a portion of the third metal wiring 152 may contact the sealing member 160.

The fourth metal wiring 153 of FIG. 5 is disposed on the third metal wiring 152 so as to be in contact with the third metal wiring 152, and at least a portion of a top surface of the fourth metal wiring 153 may contact the sealing member 160 formed on the second metal wiring 150. In some embodiments, as shown in FIG. 5, the fourth metal wring 153 may be located on the third metal wiring 152 and at both edges of the sealing member 160, and a portion of the fourth metal wiring 153 may contact the sealing member 160.

In a Joule heat wiring structure, if a wiring portion is formed in an edge region of a frit material (i.e., the sealing member 160) as in the exemplary embodiment in FIG. 4 in which wirings are stacked in two layers or as in the exemplary embodiment of FIG. 5 in which wirings are stacked in three layers, the resistance of the wiring portion can be reduced. The reduced resistance of the wiring portion can increase the amount of current flowing through the edge region and increase an actual effective width of the sealing member 160.

The third metal wiring 152 and the fourth metal wiring 153 may be formed at the same time that a metal wiring is formed on a display region 30 of a first substrate 10. The third metal wiring 152 and the fourth metal wiring 153 may be made of the same material as the metal wiring formed on the display region 30 of the first substrate 10, and may have substantially the same thickness as the metal wiring.

In the embodiment of FIG. 4, the second metal wiring 150 is formed in a non-display region 40 of the first substrate 10 at the same time that a source electrode 113a and a drain electrode 113b are formed on the display region 30. In addition, the second metal wiring 150 is made of the same material as the source electrode 113a and the drain electrode 113b. The third metal wiring 152 is formed on the second metal wiring 150 at the same time that an anode electrode is formed on the display region 30 and is made of the same material as the anode electrode. In some embodiments, the third metal wiring 152 may be formed at the same time that a cathode electrode is formed on the display region 30 and may be made of the same material as the cathode electrode.

In the embodiment of FIG. 5, the second metal wiring 150 is formed on a non-display region 40 of the first substrate 10 at the same time that a source electrode 113a and a drain electrode 113b are formed on the display region 30. In addition, the second metal wiring 150 is made of the same material as the source electrode 113a and the drain electrode 113b. The third metal wiring 152 is formed on the second metal wiring 150 at the same time that an anode electrode is formed on the display region 30, and is made of the same material as the anode electrode. The fourth metal wiring 153 is formed at the same time that a cathode electrode is formed on the display region 30, and may be made of the same material as the cathode electrode.

If the third metal wiring 152 and the fourth metal wiring 153 are formed at the same time that the metal wiring is formed on the display region 30 as described above, an additional mask process for forming the third metal wiring 152 and the fourth metal wiring 153 can be omitted. Therefore, the process can be simplified compared to the process when a wiring portion for providing heat to the sealing member 160 is formed using an additional mask process, and increased efficiency can be obtained in terms of cost and time.

FIGS. 6 thru 8 are cross-sectional views of display devices according to other exemplary embodiments of the present invention.

Referring to FIGS. 6 thru 8, each of the display devices according to the current exemplary embodiments is different from the display device according to the exemplary embodiment of FIG. 3 in that a cross sections of a second metal wiring 154, 155 or 156, which is perpendicular to a direction in which the second metal wiring 154, 155 or 156s extends, is shaped like a trench, and in that a sealing member 160 fills the trench of the second metal wiring 154, 155 or 156.

The cross-section of the second metal wiring 154, 155 or 156, which is perpendicular to the direction in which the second metal wiring 154, 155 or 156 extends, may be shaped like a trench. Referring to FIG. 2, a vertical direction may be a direction in which portions 150a of the second metal wiring 150 extend, and a horizontal direction may be a direction in which portions 150b of the second metal wiring 150 extend.

Each of the display devices may further include one or more insulating layers formed on a display region 30 and a non-display region 40 thereof. In some embodiments, each of the insulating layers may include at least one of a buffer layer 121, 122 or 123 (see FIGS. 6, 7 and 8, respectively) a gate insulating layer 131, 132 or 133, and an interlayer insulating film 141, 142 or 143. The buffer layer 121, 122 or 123, the gate insulating layer 131, 132 or 133, and the interlayer insulating film 141, 142 or 143 have the same properties as those described above with reference to FIGS. 1 thru 3.

The second metal wiring 154, 155 or 156 may be formed on the insulating layers so as to conform thereto. In some embodiments, the second metal wiring 154, 155 or 156 may be formed on the insulating layers so as to be in contact with the insulating layers, and there may be substantially no space between the second metal wiring 154, 155 or 156 and the insulating layers.

In FIGS. 6 thru 8, various embodiments in which the trench of the second metal wiring 154, 155 or 156 is formed in one insulating layer are illustrated. Referring to FIG. 6, the trench of the second metal wiring 154 may be formed in an interlayer insulating film 141 of the insulating layer. Referring to FIG. 7, the trench of the second metal wiring 155 may be formed in the interlayer insulating film 142 and the gate insulating layer 132 of the insulating layer. Referring to FIG. 8, the trench of the second metal wiring 156 may be formed in the interlayer insulating film 143, the gate insulating layer 133, and the buffer layer 123 of the insulating layer. In the exemplary embodiments of FIGS. 6 thru 8, the trench of the second metal wiring 154, 155 or 156 is formed to a depth equal to a total depth of one insulating layer. However, the trench of the second metal wiring 154, 155 or 156 can also be formed to a depth equal to one-half the depth of one insulating layer. That is, the trench of the second metal wiring 154, 155 or 156 can be formed to various depths.

If the second metal wiring 154, 155 or 156 is shaped like a trench, and if the sealing member 160 fills the trench of the second metal wiring 154, 155 or 156 as in the current exemplary embodiments, the adhesion area of the sealing member 160 to the second metal wiring 154, 155 or 156 can be increased. That is, if the second metal wiring 154, 155 or 156 is trench-shaped, the area of the second metal wiring 154, 155 or 156 formed on a first substrate 10 increases. The increased area of the second metal wiring 154, 155 or 156 increases the contact area between the second metal wiring 154, 155 or 156 and the sealing member 160, thus improving interface adhesion. Accordingly, since the sealing member 160 can melt and harden more easily, the sealing process can be performed more efficiently, and mechanical strength can be increased.

In addition, if the second metal wiring 154, 155 or 156 is shaped like a trench, and if the sealing member 160 fills the trench of the second metal wiring 154, 155 or 156 as in the current exemplary embodiments, the phenomenon of Newton's rings caused by a height resulting from a thickness of the sealing member 160 can be improved. That is, when the second metal wiring 154, 155 or 156 is shaped like a trench, the sealing member 160 may fill the trench of the second metal wiring 154, 155 or 156. Therefore, a gap between the second metal wiring 154, 155 or 156 and a second substrate 20 can be reduced, and a gap between the first substrate 10 and the second substrate 20 can be reduced to approximately 1 μm. Accordingly, this can improve the phenomenon of Newton's rings caused by the height resulting from the thickness of the sealing member 160.

FIGS. 9 and 10 are cross-sectional views of display devices according to other exemplary embodiments of the present invention.

Referring to FIGS. 9 and 10, each of the display devices according to the current exemplary embodiments is different from the exemplary embodiment of FIG. 8 in that the height of a bottom surface of a trench of a second metal wiring 157 (FIG. 9) or 158 (FIG. 10) changes in a direction perpendicular to a direction in which the second metal wiring 157 or 158 extends.

Referring to FIG. 9, the second metal wiring 157 may include a plurality of trenches in the direction perpendicular to the direction in which the second metal wiring 157 extends. The trenches may be formed to the same depth on a first substrate 10. In the embodiment of FIG. 9, bottom surfaces of the trenches are all formed on the first substrate 10. However, the present invention is not limited thereto, and the bottom surfaces of the trenches may be formed at any positions in an insulating layer on the first substrate 10.

Referring to FIG. 10, the height of the bottom surface of the trench of the second metal wiring 158 may change in the direction perpendicular to the direction in which the second metal wiring 158 extends. The display device according to the current exemplary embodiment of FIG. 10 is different from the display device according to the exemplary embodiment of FIG. 9 in that the second metal wiring 158 includes a plurality of trenches and in that bottom surfaces of the trenches of the second metal wiring 158 are all at different heights.

If the second metal wiring 157 or 158 is shaped like a trench, and if the height of a bottom surface of the trench of the second metal wiring 157 or 158 changes in the direction perpendicular to the direction in which the second metal wiring 157 or 158 extends as in the current exemplary embodiments, the adhesion area of a sealing member 160 relative to the second metal wiring 157 or 158 can be increased. That is, if the second metal wiring 157 or 158 is trench-shaped, and if the height of the bottom surface of the trench of the second metal wiring 157 or 158 changes, the area of the second metal wiring 157 or 158 formed on the first substrate 10 increases. The increased area of the second metal wiring 157 or 158 increases the contact area between the second metal wiring 157 or 158 and the sealing member 160, thus improving interface adhesion. Accordingly, since the sealing member 160 can melt and harden more easily, a sealing process can be performed more efficiently, and mechanical strength can be increased.

FIG. 11 is a cross-sectional view of a display device according to another exemplary embodiment of the present invention.

Referring to FIG. 11, the display device according to the current exemplary embodiment is different from the exemplary embodiment of FIG. 8 in that an insulating layer includes one or more protrusions on a surface thereof which contacts a second metal wiring 159.

The insulating layer on a non-display region of a first substrate 10 may include one or more protrusions on the surface thereof which contacts the second metal wiring 159. The second metal wiring 159 may be formed on the insulating layer so as to conform thereto. Therefore, since a portion of the second metal wiring 159, which is located on the protrusions of the insulating layer, is also shaped like protrusions, the second metal wiring 159 may include one or more protrusions on a surface thereof which contacts a sealing member 160.

If the second metal wiring 159 is shaped like a trench and includes one or more protrusions due to one or more protrusions of the insulating layer as in the current exemplary embodiment, the adhesion area of the sealing member 160 relative to the second metal wiring 159 can be increased. That is, if the second metal wiring 159 is trench-shaped and includes one or more protrusions, the area of the second metal wiring 159 is increased by the protrusions of the second metal wiring 159. The increased area of the second metal wiring 159 increases the contact area between the second metal wiring 159 and the sealing member 160, thus improving interface adhesion. Accordingly, since the sealing member 160 can melt and harden more easily, a sealing process can be performed more efficiently, and mechanical strength can be increased.

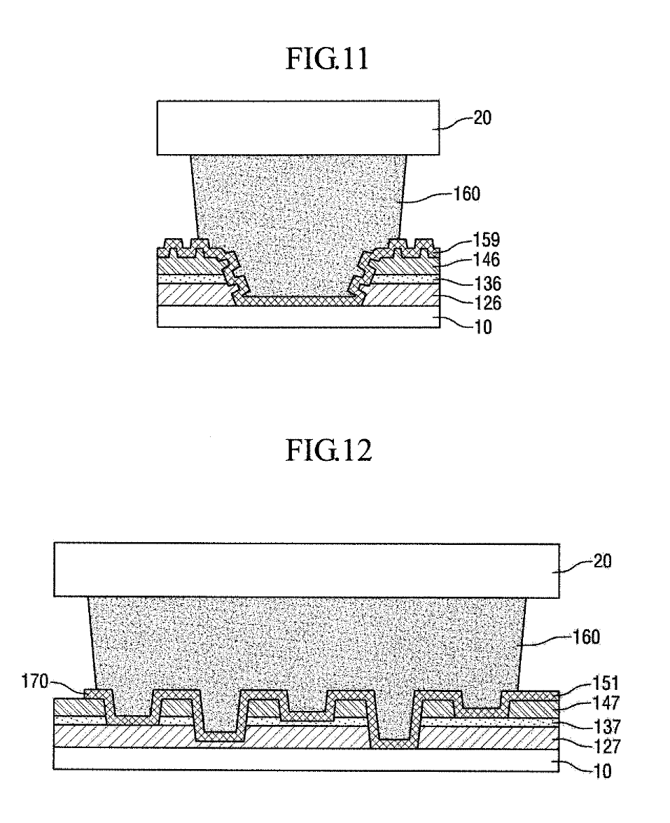

FIG. 12 is a cross-sectional view taken along the line XII-XII of FIG. 2.

Referring to FIG. 12, the display device according to the current exemplary embodiment includes a metal wiring for providing heat to the sealing member 160. A cross section of the metal wiring, which is perpendicular to a direction in which the metal wiring extends, may be shaped like a trench, and a height of a bottom surface of the trench of the metal wiring may change along the direction in which the metal wiring extends.

The embodiment of FIG. 12 is different from the embodiment of FIG. 10 in that the height of the bottom surface of the trench of the metal wiring changes in the direction in which the metal wiring extends.

The display device may include one or more additional wirings 151 for receiving power from an external source. Each of the additional wirings 151 may be an extension of the second metal wiring 150 or a separate wiring additionally connected to the second metal wiring 150. The additional wirings 151 may be made of conductive metal.

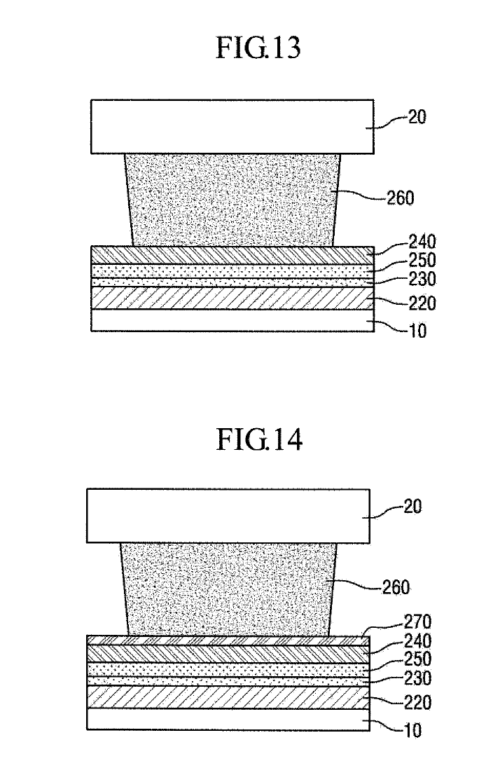

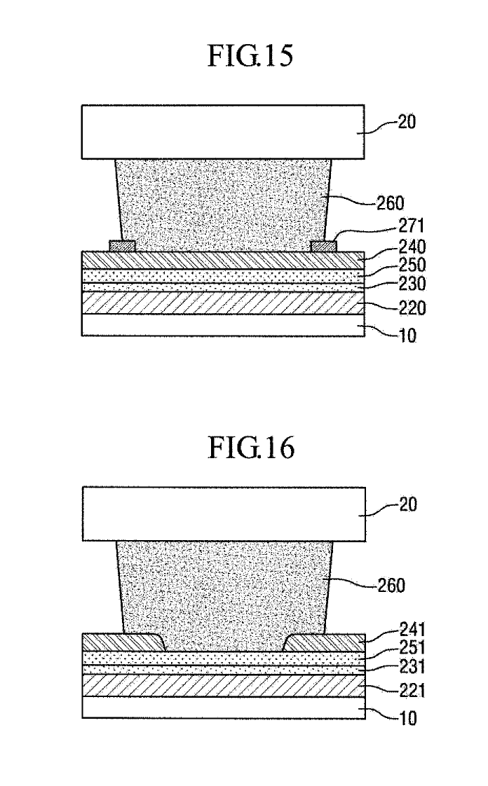

FIG. 13 is a cross-sectional view of a display device according to another exemplary embodiment of the present invention.

Referring to FIG. 13, the display device according to the current exemplary embodiment includes a first substrate 10, a first metal wiring formed on a display region 30 (FIG. 1) of the first substrate 10, an intermediate layer formed on anon-display region 40 of the first substrate 10 and including one or more insulating layers and a second metal wiring 250, a sealing member 260 formed on the intermediate layer, and a second substrate 20 formed on the sealing member 260 so as to face the first substrate 10.

The first substrate 10, the sealing member 260 and the second substrate 20 of the display device according to the current exemplary embodiment are substantially the same as the first substrate 10, the sealing member 160 and the second substrate 20 described above with reference to FIGS. 1 thru 3, and thus a redundant description thereof is omitted.

The display device includes the intermediate layer formed on the non-display region 40 of the first substrate 10. The intermediate layer may be positioned in the middle between the first substrate 10 and the sealing member 260. The intermediate layer may include one or more insulating layers and the second metal wiring 250. In some embodiments, the insulating layers may include one or more of a buffer layer 220, a gate insulating layer 230 and an interlayer insulating film 240. The buffer layer 220, the gate insulating layer 230 and the interlayer insulating film 240 are substantially the same as the buffer layer 120, the gate insulating layer 130 and the interlayer insulating film 140 described above with reference to FIGS. 1 thru 3, and thus a redundant description thereof is omitted.

The intermediate layer includes the second metal wiring 250. In some embodiments, after the buffer layer 220 and the gate insulating layer 230 are sequentially stacked on the non-display region 40 of the first substrate 10, the second metal wring 250 may be formed on the gate insulating layer 230, and then the interlayer insulating film 240 may be formed on the second metal wiring 250.

The second metal wiring 250 may be formed on the non-display region 40 of the first substrate 10 at the same time that the first metal wiring is formed on the display region 30 of the first substrate 10. The second metal wiring 250 may be made of the same material as the first metal wiring, and may have substantially the same thickness as the first metal wiring.

The second metal wiring 250 may be supplied with and receive power, and may provide heat to the sealing member 260. When a voltage is applied to the second metal wiring 250, the second metal wiring 250 generates Joule heat, and the sealing member 260 (i.e., a thermosetting material) is melted and hardened by the Joule heat supplied from the second metal wiring 250, thereby bonding the first substrate 10 and the second substrate 20 together.

In the current exemplary embodiment of the present invention, the second metal wiring 250 providing heat to the sealing member 260 may be formed on the non-display region 40 of the first substrate 10 at the same time that the first metal wiring is formed on the display region 30 of the first substrate 10. For example, if the first metal wiring is a gate electrode 112, when the gate electrode 112 is formed on the display region 30, the second metal wiring 250 may also be formed on the non-display region 40 using the same material as that of the gate electrode 112 formed on the display region 30 and to a thickness substantially equal to that of the gate electrode 112. In some embodiments, the first metal wiring and the second metal wiring 250 may be Mo.

If the second metal wiring 250 is formed at the same time that the first metal wiring is formed on the display region 30 as described above, an additional mask process for forming the second metal wiring 250 can be omitted. Therefore, the process can be simplified compared to the process when a wiring portion for providing heat to the sealing member 260 is formed using an additional mask process, and increased efficiency can be obtained in terms of cost and time.

FIG. 14 is a cross-sectional view of a display device according to another exemplary embodiment of the present invention.

Referring to FIG. 14, the display device according to the current exemplary embodiment is different from the display device according to the exemplary embodiment of FIG. 13 in that it further includes a third metal wiring 152 (as in FIGS. 4 and 5) formed in a display region 30 (FIG. 1) and a fourth metal wiring 270 (FIG. 14) formed on an intermediate layer in a non-display region 40.

The fourth metal wiring 270 may be formed on the intermediate layer so as to contact a sealing member 260. The fourth metal wiring 270 may be supplied with power and provide heat to the sealing member 260. In a Joule heat wiring structure, if wirings are stacked in two layers as in the exemplary embodiment of FIG. 14, the resistance of a wiring portion can be reduced. The reduced resistance of the wiring portion can increase the amount of current flowing through the wiring portion, and can increase an actual effective width of the sealing member 260.

The third metal wiring 152 and the fourth metal wiring 270 may be formed at the same time that a metal wiring is formed on the display region 30 of a first substrate 10. The third metal wiring 152 and the fourth metal wiring 270 may be made of the same material as the metal wiring formed on the display region 30 of the first substrate 10, and may have substantially the same thickness as the metal wiring. For example, if a first metal wiring is a gate electrode 112 (FIG. 1), and if the second metal wiring 250 is made of the same material as the gate electrode 112, the third metal wiring 152 may be one of a source electrode 113a, a drain electrode 113b, an anode electrode and a cathode electrode, and the fourth metal wiring 270 may be formed at the same time that the third metal wiring 152 using the same material as that of the third metal wiring 152 is formed.

If the third metal wiring 152 and the fourth metal wiring 270 are formed at the same time that the metal wiring is formed in the display region 30 as described above, an additional mask process for forming the third metal wiring 152 and the fourth metal wiring 270 can be omitted. Therefore, the process can be simplified as compared to the process when the wiring portion for providing heat to the sealing member 260 is formed using an additional mask process, and increased efficiency can be obtained in terms of cost and time.

FIG. 15 is a cross-sectional view of a display device according to another exemplary embodiment of the present invention.

Referring to FIG. 15, the display device according to the current exemplary embodiment is different from the display device according to the exemplary embodiment of FIG. 13 in that it further includes a fifth metal wiring 271 formed on an intermediate layer so as to be in contact with the intermediate layer.

The fifth metal wiring 271 is formed on the intermediate layer so as to be in contact with the intermediate layer, and at least a portion of a top surface of the fifth metal wiring 271 may contact a sealing member 260 formed on the intermediate layer. In some embodiments, as shown in FIG. 15, the fifth metal wiring 271 may be located on the intermediate layer and at both edges of the sealing member 260, and a portion of the fifth metal wiring 271 may contact the sealing member 260.

In a Joule heat wiring structure, if a wiring portion is formed in an edge region of a frit material (i.e., the sealing member 160) as in the exemplary embodiment in FIG. 15 in which wirings are stacked in two layers, the resistance of the wiring portion can be reduced. The reduced resistance of the wiring portion can increase the amount of current flowing through the edge region, and can increase an actual effective width of the sealing member 260.

FIG. 16 is a cross-sectional view of a display device according to another exemplary embodiment of the present invention.

Referring to FIG. 16, the display device according to the current exemplary embodiment is different from the display device according to the exemplary embodiment of FIG. 13 in that a cross section of an interlayer insulating film 241, which is perpendicular to a direction in which an intermediate layer extends, is shaped like a trench, and in that a sealing member 260 fills the trench of the interlayer insulating film 241.

The cross section of the interlayer insulating film 241, which is perpendicular to the direction in which the intermediate layer extends, may be shaped like a trench. In this case, the phenomenon of Newton's rings, caused by a height resulting from a thickness of the sealing member 260, can be improved. That is, when the interlayer insulating film 241 is shaped like a trench, the sealing member 260 may fill the trench of the interlayer insulating film 241. Therefore, a gap between the interlayer insulating film 241 and a second substrate 20 can be reduced, and a gap between a first substrate 10 and the second substrate 20 can be reduced to approximately 1 μm. Accordingly, this can improve the phenomenon of Newton's rings caused by the height resulting from the thickness of the sealing member 260.

FIG. 17 is a cross-sectional view of a display device according to another exemplary embodiment of the present invention.

Referring to FIG. 17, the display device according to the current exemplary embodiment is different from the display device according to the exemplary embodiment of FIG. 16 in that it further includes a sixth metal wiring formed in a display region 30 and a seventh metal wiring 272 formed on an intermediate layer on a non-display region 40.

The seventh metal wiring 272 may be formed on the intermediate layer so as to conform with the intermediate layer. In some embodiments, the seventh metal wiring 272 may be formed on the intermediate layer so as to be in contact with the intermediate layer, and there may be substantially no space between the seventh metal wiring 272 and the intermediate layer.

The seventh metal wiring 272 may be formed on the intermediate layer so as to contact a sealing member 260. The seventh metal wiring 272 may be supplied with power and provide heat to the sealing member 260. In a Joule heat wiring structure, if wirings are stacked in multiple layers as in the exemplary embodiment of FIG. 17, the resistance of a wiring portion can be reduced. The reduced resistance of the wiring portion can increase the amount of current flowing through the wiring portion and increase an actual effective width of the sealing member 260.

The sixth metal wiring and the seventh metal wiring 272 may be formed at the same time that a metal wiring is formed on the display region 30 of a first substrate 10. The sixth metal wiring and the seventh metal wiring 272 may be made of the same material as the metal wiring formed on the display region 30 of the first substrate 10, and may have substantially the same thickness as the metal wiring. For example, if a first metal wiring is a gate electrode 112 and if a second metal wiring 251 is made of the same material as the gate electrode 112, the sixth metal wiring may be one of a source electrode 113a, a drain electrode 113b, an anode electrode and a cathode electrode, and the seventh metal wiring 272 may be formed at the same time as the sixth metal wiring using the same material as that of the sixth metal wiring.

Each of the sixth metal wiring and the seventh metal wiring 272 may include a plurality of wirings. For example, the sixth metal wiring may be a stack of two or more of the source electrode 113a, the drain electrode 113b, the anode electrode and the cathode electrode, and the seventh metal wiring 272 may be formed at the same time as the sixth metal wiring in the same way as the sixth metal wiring.

If the sixth metal wiring and the seventh metal wiring 272 are formed at the same time that the metal wiring is formed on the display region 30 as described above, an additional mask process for forming the sixth metal wiring and the seventh metal wiring 272 can be omitted. Therefore, the process can be simplified as compared to the process when the wiring portion for providing heat to the sealing member 260 is formed using an additional mask process, and increased efficiency can be obtained in terms of cost and time.

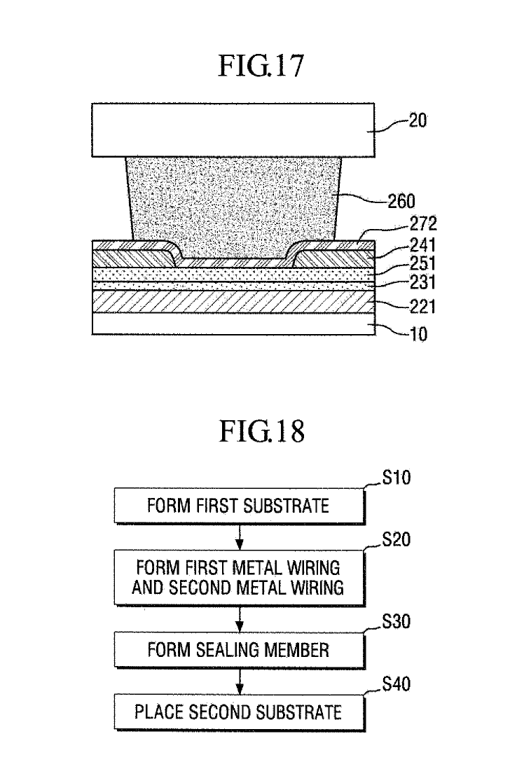

FIG. 18 is a flowchart illustrating a method of manufacturing a display device according to an exemplary embodiment of the present invention.

In the method of manufacturing a display device according to the current exemplary embodiment, a first substrate including a display region and a non-display region surrounding the display region is formed (operation S10). The first substrate is substantially the same as the first substrate 10 described above with reference to FIGS. 1 thru 3, and thus a redundant description thereof is omitted.

A first metal wiring is formed on the display region of the first substrate, and, at the same time, a second metal wiring is formed on the non-display region using the same material as that of the first metal wiring, and to a thickness equal to that of the first metal wiring (operation S20). As described above, if the first metal wiring is a gate electrode, when the gate electrode is formed on the display region, the second metal wiring may also be formed on the non-display region using the same material as that of the gate electrode formed on the display region, and to a thickness substantially equal to that of the gate electrode. When the first metal wiring is a source electrode or a drain electrode, the second metal wiring may be formed at the same time as the source electrode or the drain electrode. When the first metal wiring is an anode electrode or a cathode electrode, the second metal wiring may also be formed in the same way as described above.

If the second metal wiring is formed at the same time that the first metal wiring is formed on the display region as described above, an additional mask process for forming the second metal wiring can be omitted. Therefore, the process can be simplified compared to the process when a wiring portion for providing heat to a sealing member is formed using an additional mask process, and increased efficiency can be obtained in terms of cost and time.

The forming of the second metal wiring may include forming the second metal wiring such that a cross section of the second metal wiring, which is perpendicular to a direction in which the second metal wiring extends, is shaped like a trench. The sealing member may fill the trench of the second metal wiring.

If the second metal wiring is shaped like a trench, and if the sealing member fills the trench of the second metal wiring as in the current exemplary embodiment, the adhesion area of the sealing member to the second metal wiring can be increased. That is, if the second metal wiring is trench-shaped, the area of the second metal wiring formed on the first substrate increases. The increased area of the second metal wiring increases the contact area between the second metal wiring and the sealing member, thus improving interface adhesion. Accordingly, since the sealing member can melt and harden more easily, the sealing process can be performed more efficiently, and mechanical strength can be increased.

In addition, if the second metal wiring is shaped like a trench, and if the sealing member fills the trench of the second metal wiring as in the current exemplary embodiment, the phenomenon of Newton's rings, caused by a height resulting from a thickness of the sealing member, can be improved. That is, when the second metal wiring is shaped like a trench, the sealing member may fill the trench of the second metal wiring. Therefore, a gap between the second metal wiring and a second substrate can be reduced, and a gap between the first substrate and the second substrate can be reduced to approximately 1 μm. Accordingly, this can improve the phenomenon of Newton's rings, caused by the height resulting from the thickness of the sealing member.

Next, a third metal wiring may be formed on the second metal wiring so as to be in contact with the second metal wiring. At least a portion of a top surface of the third metal wiring may contact the sealing member. In some embodiments, when an anode electrode is formed in the display region, the third metal wiring may also be formed using the same material as that of the anode electrode, and to a thickness equal to that of the anode electrode.

A fourth metal wiring may be formed on the third metal wiring so as to be in contact with the third metal wiring. At least a portion of a top surface of the fourth metal wiring may contact the sealing member. In some embodiments, when a cathode electrode is formed in the display region, the fourth metal wiring may also be formed using the same material as that of the cathode electrode, and to a thickness equal to that of the cathode electrode.

The sealing member is formed on the second metal wiring (operation S30). The sealing member is substantially the same as the sealing member 160 described above with reference to FIGS. 1 thru 3, and thus a redundant description thereof is omitted.

The second substrate is placed on the sealing member so as to face the first substrate (operation S40). The second substrate is substantially the same as the second substrate described above with reference to FIGS. 1 thru 3, and thus a redundant description thereof is omitted.

The second metal wiring may be supplied with power and provide heat to the sealing member. The second metal wiring may include one or more additional wirings to be supplied with power. The additional wirings are substantially the same as the additional wirings 151 described above with reference to FIGS. 1 thru 3, and thus a redundant description thereof is omitted.

Exemplary embodiments of the present invention provide at least one of the following advantages.

A mask process, required to form a wiring portion during a sealing process using Joule heat, can be omitted. Therefore, the wiring portion can be formed without an additional mask process, thereby simplifying the sealing process. This method is more efficient in sealing a display device than a laser fusion-bonding method.

Since the wiring portion is formed in an edge region of a sealing member, the resistance of the wiring portion can be reduced while the amount of current flowing through the edge region is increased. Also, an actual effective width of the cell sealing member can be increased.

A trench structure formed on a lower substrate (a low temperature polysilicon (LTPS) substrate) can increase mechanical strength and improve the reliability of impact resistance.

Furthermore, a trench which is formed can reduce a height of the sealing member which provides sealing between the lower substrate and an upper substrate. Accordingly, the phenomenon of Newton's rings, caused by the height of the sealing member, can be improved.

The wiring portion for generating Joule heat is formed in a multilayer wiring structure such as a double-layer wiring structure or a triple-layer wiring structure, instead of a single-layer wiring structure. Thus, this can reduce wiring resistance and increase the uniformity of voltage distribution, thereby improving bonding characteristics between the lower substrate and the upper substrate.

However, the effects of the present invention are not restricted to the ones set forth herein. The above and other effects of the present invention will become more apparent to one of ordinary skill in the art to which the present invention pertains by referencing the claims.

Although the present invention has been described in connection with the exemplary embodiments of the present invention with reference to the accompanying drawings, it will be apparent to those skilled in the art that various modifications and changes may be made thereto without departing from the scope and spirit of the invention. Therefore, it should be understood that the above embodiments are not limiting, but are illustrative in all aspects.

What is claimed is:

1. A display device, comprising:
a first substrate including a display region and a non-display region surrounding the display region;
a first metal wiring formed in the display region of the first substrate;
a second metal wiring formed in the non-display region of the first substrate;
a sealing member formed on the second metal wiring; and
a second substrate disposed on the sealing member so as to face the first substrate;
wherein the first metal wiring and the second wiring are made of a same material.

2. The display device of claim 1, wherein the first metal wiring and the second metal wiring have substantially a same thickness.

3. The display device of claim 1, further comprising a third metal wiring formed on the second metal wiring so as to be in contact with the second metal wiring, wherein at least a portion of a top surface of the third metal wiring contacts the sealing member.

4. The display device of claim 3, wherein the display region comprises a source electrode, a drain electrode and an anode electrode, wherein the first metal wiring is the source electrode and the drain electrode, and wherein the third metal wiring is made of a same material as the anode electrode.

5. The display device of claim 3, further comprising a fourth metal wiring formed on the third metal wiring so as to be in contact with the third metal wiring, wherein at least a portion of a top surface of the fourth metal wiring contacts the sealing member.

6. The display device of claim 5, wherein the display region further comprises a cathode electrode, and wherein the fourth metal wiring is made of a same material as the cathode electrode.

7. The display device of claim 1, wherein a cross section of the second metal wiring, which is perpendicular to a direction in which the second metal wiring extends, is shaped like a trench, and the sealing member fills the trench of the second metal wiring.

8. The display device of claim 7, further comprising at least one insulating layer formed in the display region and the non-display region, wherein the second metal wiring is formed on said at least insulating layer so as to conform thereto.

9. The display device of claim 8, wherein said at least one insulating layer comprises at least one protrusion located on a surface thereof which contacts the second metal wiring.

10. The display device of claim 8, wherein said at least one insulating layer comprises an interlayer insulating film, a gate insulating layer disposed under the interlayer insulating film, and a buffer layer disposed under the gate insulating layer, and wherein a bottom surface of the trench of the second metal wiring is located within said at least one insulating layer.

11. The display device of claim 7, wherein a height of a bottom surface of the trench of the second metal wiring changes in a direction perpendicular to the direction in which the second metal wiring extends.

12. The display device of claim 1, wherein the second metal wiring provides heat to the sealing member when supplied with power, and comprises at least one additional wiring in order to be supplied with the power.

13. A display device, comprising:
a first substrate including a display region and a non-display region surrounding the display region;
a metal wiring formed in the non-display region of the first substrate and shaped like a trench;
a sealing member formed on the metal wiring and filling the trench of the metal wiring; and
a second substrate disposed on the sealing member so as to face the first substrate.

14. The display device of claim 13, wherein a cross section of the metal wiring, which is perpendicular to a direction in which the metal wiring extends, is shaped like a trench.

15. The display device of claim 14, wherein a height of a bottom surface of the trench of the metal wiring changes in a direction perpendicular to the direction in which the metal wiring extends.

16. The display device of claim 14, wherein a height of a bottom surface of the trench of the metal wiring changes in the direction in which the metal wiring extends.

17. The display device of claim 14, wherein a bottom surface of the trench of the metal wiring comprises at least one protrusion located on a surface thereof which contacts the sealing member.

18. A display device, comprising:
a first substrate including a display region and a non-display region surrounding the display region;
a first metal wiring formed in the display region of the first substrate;
an intermediate layer formed in the non-display region of the first substrate and including at least one insulating layer and a second metal wiring;
a sealing member formed on the intermediate layer; and
a second substrate disposed on the sealing member so as to face the first substrate;
wherein the first metal wiring and the second wiring are made of a same material.

19. The display device of claim 18, wherein the first metal wiring and the second metal wiring have substantially a same thickness.

20. The display device of claim 19, wherein the display region comprises a gate electrode, and wherein the first metal wiring is the gate electrode.

21. The display device of claim 20, wherein the intermediate layer comprises an interlayer insulating film, and wherein the interlayer insulating film is located on the second metal wiring.

22. The display device of claim 21, wherein a cross section of the interlayer insulating film, which is perpendicular to a direction in which the intermediate layer extends, is shaped like a trench, and wherein the sealing member fills the trench of the interlayer insulating film.

23. The display device of claim 22, further comprising:
at least one third metal wiring formed in the display region; and
at least one fourth metal wiring formed n the intermediate layer;
wherein said at least one third metal wiring and said at least one fourth metal wiring are made of a same material.

24. The display device of claim 18, wherein the second metal wiring provides heat to the sealing member when supplied with power, and comprises at least one additional wiring in order to be supplied with the power.

25. A method of manufacturing a display device, the method comprising the steps of:
forming a first substrate which includes a display region and a non-display region surrounding the display region;
forming a first metal wiring in the display region of the first substrate;
forming a second metal wiring in the non-display region at a same time that the first metal wiring is formed using a same material as that of the first metal wiring, and to a thickness equal to a thickness of the first metal wiring;
forming a sealing member on the second metal wiring; and
placing a second substrate on the sealing member so as to face the first substrate.

26. The method of claim 25, further comprising the step of forming a third metal wiring on the second metal wiring so as to be in contact with the second metal wiring, wherein at least a portion of a top surface of the third metal wiring contacts the sealing member.

27. The method of claim 25, wherein the step of forming the second metal wiring comprises forming the second metal wiring so that a cross section of the second metal wiring, which is perpendicular to a direction in which the second metal wiring extends, is shaped like a trench, and wherein the sealing member fills the trench of the second metal wiring.

28. The method of claim 27, further comprising the step of forming at least one insulating layer in the display region and the non-display region, wherein the second metal wiring is formed on said at least one insulating layer so as to conform therewith.

29. The method of claim 28, wherein said at least one insulating layer comprises at least one protrusion located on a surface thereof which contacts the second metal wiring.

30. The method of claim 28, wherein said at least one insulating layer comprises an interlayer insulating film, a gate insulating layer disposed under the interlayer insulating film, and a buffer layer disposed under the gate insulating layer, and wherein a bottom surface of the trench of the second metal wiring is located within said at least one insulating layer.

31. The method of claim 27, further comprising the step of forming a bottom surface of the trench of the second metal wiring so that a height of the bottom surface of the trench of the second metal wiring changes in a direction perpendicular to a direction in which the second metal wiring extends.

32. The method of claim 25, further comprising the step of receiving power and providing heat to the sealing member by using the second metal wiring, wherein the second metal wiring comprises at least one additional wiring in order to be supplied with the power.
